(19) United States
(12) Patent Application Publication
(10) Pub. No.: US 2023/0202126 A1
(43) Pub. Date: Jun. 29, 2023

(54) LOW DIELECTRIC LOSS NON-WOVEN FABRIC, PREPARATION METHOD THEREOF AND USE THEREOF

(71) Applicant: SHENGYI TECHNOLOGY CO., LTD., Dongguan City (CN)

(72) Inventors: Wei LIANG, Dongguan City (CN); Songgang CHAI, Dongguan City (CN); Qianfa LIU, Dongguan City (CN); Liangpeng HAO, Dongguan City (CN)

(21) Appl. No.: 17/980,053

(22) Filed: Nov. 3, 2022

(30) Foreign Application Priority Data
Dec. 24, 2021 (CN) 202111598907.9

(51) Int. Cl. B29C 70/50; B29C 70/88; B29C 70/54; C08J 5/24

(52) U.S. Cl. CPC B29C 70/50; B29C 70/88; B29C 70/54; C08J 5/249; C08J 5/244; B29K 2105/089

(57) ABSTRACT

Provided are a low dielectric loss non-woven fabric, a preparation method thereof and use thereof. The low dielectric loss non-woven fabric is composed of an inorganic fiber and a binder, and the binder is any one or a combination of at least two of a fluorine-containing resin emulsion, a polyolefin emulsion, a polyphenylene ether resin or a cyanate ester resin. The non-woven fabric of the present application has good dielectric properties and obvious strengthening effect, and can meet various performance requirements for copper clad laminate materials in the field of high-frequency communication.

This application claims priority to Chinese Patent Application No. 202111598907.9, filed on Dec. 24, 2021, the contents of which are incorporated herein in its entirety by reference.

### TECHNICAL FIELD

The present application belongs to the technical field of laminates, and relates to a low dielectric loss non-woven fabric, a preparation method thereof and use thereof.

### BACKGROUND

The copper clad laminate has been widely used in mobile phones, computers, vending machines, communication base stations, satellites, wearable devices, unmanned vehicles, unmanned aerial vehicles, intelligent robots and other fields, which is one of the key basic materials in the electronic communication and information industry. The fluorine-containing resin, represented by polytetrafluoroethylene (PTFE), have many excellent properties that are incomparable by any other polymer resins, such as low dielectric constant, low dielectric loss, high thermal stability and high chemical stability, which is an ideal base material for the copper clad laminate. The polymer chain of fluorine-containing resin is relatively flexible, and generally, it is necessary to introduce inorganic materials to improve the mechanical strength of the fluorine-containing resin-based copper clad laminate. For example, CN101857708A discloses a solution that a glass fabric is impregnated with a fluorine-containing resin mixture and baked to obtain a PTFE varnished cloth; however, since the glass fabric adopts the warp and weft weaves, the prepared PTFE copper clad laminate is not uniform, and has different dielectric constant, coefficient of thermal expansion (CTE) and dielectric loss at different positions, resulting in different signal transmission delays at different positions.

With the increasing requirement for isotropy of high-frequency copper clad laminate substrates, it is necessary to develop an isotropic reinforcing material, so that the PTFE composite material can have excellent Dk consistency, extremely low dielectric loss, and also better mechanical strength than the PTFE film that contains no reinforcing material. Currently, there exists no isotropic reinforcing material with extremely low dielectric loss.

Conventional non-woven fabrics have the characteristics of reinforcement and isotropy, but generally adopt epoxy binders, acrylate binders, melamine binders or polyvinyl alcohol binders, which have large dielectric loss. The epoxy binders, acrylate binders, melamine binders or polyvinyl alcohol binders have large dielectric loss, which is much larger than the dielectric loss of those used in mainstream high-frequency products, such as hydrocarbon resins, polyphenylene ether resins or PTFE resins. If using the conventional non-woven fabrics, the high-frequency products will lose the dielectric advantages of hydrocarbon resins, polyphenylene ether resins or PTFE resins. Therefore, those skilled in the art take advantage of the glass fabric's characteristics of reinforcement and low dielectric loss, and consider how to overcome the anisotropy caused by the warp and weft weaves of glass fabric; for example, glass fabric splitting, or resin-impregnating pretreatment of the glass fabric can be adapted to reduce the defects caused by warp and weft weaves.

### SUMMARY

In view of the deficiencies of the prior art, an object of the present application is to provide a low dielectric loss non-woven fabric, a preparation method thereof and use thereof. The non-woven fabric of the present application has good dielectric properties and obvious strengthening effect, and can meet various performance requirements for copper clad laminate materials in the field of high-frequency communication.

In order to achieve the object, the present application adopts the following technical solutions.

In one aspect, the present application provides a low dielectric loss non-woven fabric, and the low dielectric loss non-woven fabric is composed of an inorganic fiber and a binder, and the binder is any one or a combination of at least two of a fluorine-containing resin emulsion, a polyolefin emulsion, a polyphenylene ether resin or a cyanate ester resin.

In the present application, by using the binder, the non-woven fabric has low dielectric loss, good uniformity, uniform thickness, uniform fiber orientation distribution and high tensile strength, and can be added with plenty of dielectric fillers when being impregnated with the low dielectric loss resin to prepare low dielectric loss high-frequency copper clad laminates.

In the present application, the low dielectric loss non-woven fabric refers to that a dielectric loss of the non-woven fabric is less than 0.0015 (10 GHz).

Preferably, a weight percentage of the inorganic fiber is 60-95% in the low dielectric loss non-woven fabric (such as 60%, 62%, 65%, 68%, 70%, 73%, 75%, 78%, 80%, 83%, 85%, 88%, 90%, 93% or 95%), and a weight percentage of the binder is 5-40% (such as 5%, 8%, 10%, 15%, 18%, 20%, 23%, 25%, 28%, 30%, 33%, 35%, 38% or 40%).

The binder is any one or a combination of at least two of a fluorine-containing resin emulsion, a polyolefin emulsion, a polyphenylene ether resin or a cyanate ester resin. The fluorine-containing resin emulsion, polyolefin emulsion, polyphenylene ether resin or cyanate ester resin can be dissolved and diluted to a suitable viscosity by adding a solvent as required to obtain a binder.

From the viewpoint of low dielectric properties, preferably, the binder is a fluorine-containing resin emulsion.

Preferably, the fluorine-containing resin emulsion is selected from any one or a combination of at least two of a polyperfluoroethylene propylene emulsion, a polyvinylidene fluoride emulsion, a tetrafluoroethylene-perfluoroalkyl vinyl ether copolymer emulsion, an ethylene-tetrafluoroethylene copolymer emulsion, a polychlorotrifluoroethylene emulsion or an ethylene-chlorotrifluoroethylene copolymer emulsion.

Preferably, a solid content of the fluorine-containing resin emulsion is 30-70%, such as 30%, 35%, 38%, 40%, 45%, 50%, 55%, 60%, 65% or 70%.

Preferably, a particle size of the fluorine-containing resin is 0.10-0.40 μm in the fluorine-containing resin emulsion.

In the present disclosure, the particle size of the fluorine-containing resin emulsion is measured by a laser diffraction method, and the measuring instrument was a Malvern laser particle size analyzer, model MS3000. In the present disclosure, the dielectric constant and dielectric loss are measured by SPDR (split post dielectric resonator) method, and a frequency is 10 GHz.

Preferably, the polyolefin emulsion is selected from any one or a combination of at least two of an unsaturated polybutadiene resin emulsion, a styrene-butadiene-styrene triblock copolymer (SBS) emulsion, a hydrogenated styrene-butadiene-styrene triblock copolymer (SEBS) emulsion or a styrene-butadiene resin emulsion. A solid content of the polyolefin emulsion is 30-70%, such as 30%, 35%, 38%, 40%, 45%, 50%, 55%, 60%, 65% or 70%.

Preferably, the inorganic fiber is selected from any one or a combination of at least two of an E-glass fiber, an NE-glass fiber, an L-glass fiber or a quartz fiber.

Preferably, an average diameter of the inorganic fiber is less than 10 μm, such as 9 μm, 8 μm, 7 μm, 6 μm, 5 μm, 4 μm, 3 μm, 2 μm or 1 μm, preferably 1-5 μm.

Preferably, an average length of the inorganic fiber is 1-100 mm, such as 100 mm, 90 mm, 80 mm, 70 mm, 60 mm, 50 mm, 40 mm, 30 mm, 20 mm, 10 mm or 5 mm. The average diameter and the average length of the inorganic filler in the present application are obtained by observing and measuring with scanning electron microscope.

Preferably, a mass per unit area of the low dielectric loss non-woven fabric is 20-200 g/m², such as 20 g/m², 25 g/m², 30 g/m², 35 g/m², 40 g/m², 50 g/m², 60 g/m², 80 g/m², 100 g/m², 120 g/m², 150 g/m², 180 g/m² or 200 g/m², preferably 20-100 g/m².

In another aspect, the present application provides a preparation method of the low dielectric loss non-woven fabric, which includes mixing an inorganic fiber with a binder, impregnating the fiber, subjecting them to papermaking molding, and drying them, so as to obtain the low dielectric loss non-woven fabric.

Preferably, a time of the impregnating is 40-50 min, such as 40 min, 43 min, 45 min, 48 min or 50 min.

Preferably, a temperature of the drying is 120-150° C., such as 120° C., 125° C., 130° C., 135° C., 140° C., 145° C. or 150° C.

When the binder is selected from the fluorine-containing resin emulsion, a sintering step should be performed after the drying to melt the fluorine-containing resin into a film.

Preferably, a temperature of the sintering is 220° C.-370° C., such as 220° C., 230° C., 250° C., 270° C., 290° C., 300° C., 320° C., 340° C., 360° C. or 370° C., and a time of the sintering is 28-30 min.

In another aspect, the present application provides a prepreg, and the prepreg includes the low dielectric loss non-woven fabric and a resin composition adhered thereto by impregnation.

Preferably, the resin composition is a fluorine-containing resin emulsion.

Preferably, the fluorine-containing resin emulsion is selected from any one or a combination of at least two of a polyperfluoroethylene propylene emulsion, a polyvinylidene fluoride emulsion, a tetrafluoroethylene-perfluoroalkyl vinyl ether copolymer emulsion, an ethylene-tetrafluoroethylene copolymer emulsion, a polychlorotrifluoroethylene emulsion or an ethylene-chlorotrifluoroethylene copolymer emulsion.

In another aspect, the present application provides a copper clad laminate, and the copper clad laminate includes a copper foil and the prepreg as above.

In another aspect, the present application provides a printed circuit board, and the printed circuit board includes a copper foil and the prepreg as above.

Compared with the prior art, the present application has the following beneficial effects:

The non-woven fabric of the present application has low dielectric loss, good uniformity, uniform thickness, uniform fiber orientation distribution and high tensile strength, and can be added with plenty of dielectric fillers when being impregnated with the low dielectric loss resin to prepare high-frequency copper clad laminates with low dielectric loss and high peel strength.

### DETAILED DESCRIPTION

The technical solutions of the present application are further described below through specific embodiments. It should be apparent to those skilled in the art that the embodiments are merely used for a better understanding of the present application, and should not be regarded as a specific limitation to the present application.

Raw materials used in the following examples and comparative examples are as follows:

Fluorinated ethylene propylene (FEP) resin emulsion, with a particle size of 0.20 μm, with a solid content of 50 wt %, from Japan Daikin Industries, Ltd., Brand: ND-110.

Perfluoroalkoxy (PFA) resin emulsion, with a particle size of 0.20 μm, with a solid content of 55 wt %, from Japan Daikin Industries, Ltd., Brand: AD-2CR.

PTFE resin emulsion, with a particle size of 0.25 μm, with a solid content of 55 wt %, from Japan Daikin Industries, Ltd., Brand: D210C.

Polyolefin emulsion, with a particle size of 0.1 μm, with a solid content of 45 wt %, a sample from Beijing Yanshan Petrochemical Company.

Polyphenylene ether binder: 100 parts of vinyl-modified polyphenylene ether (Mitsubishi Gas Chemical OPE-2ST) were weighted out, dissolved in a solvent of toluene, and stirred uniformly to obtain a polyphenylene ether binder.

Low-CTE (coefficient of thermal expansion) resin A: 450 g of the PTFE resin emulsion was taken, stirred and mixed at a high speed for 2 h to obtain a uniform resin composition.

Thermosetting resin A: 30 parts by weight of ethylene-propylene rubber (with a number average molecular mass of 80000 g/mol, from America Lion Chemical Corporation), 40 parts by weight of polybutadiene (with a molecular mass of 3200 g/mol, from Nippon Soda Co., Ltd.), and 2 parts by weight of benzoyl peroxide (from Shanghai Kang Lang Biological Technology Co., Ltd.) were dissolved in 50 parts by weight of xylene and mixed uniformly, so as to obtain a uniform resin composition.

Thermosetting resin B: 70 parts by weight of methyl methacrylate-terminated polyphenylene ether resin (MMA-PPE) (SA9000, from SABIC) were mixed with 70 parts by weight of toluene that was used as a solvent, and dissolved completely to obtain a functionalized polyphenylene ether resin solution, then 30 parts by weight of styrene-butadiene copolymer R100 (from Sartomer company) were added as a cross-linking curing agent, 3 parts by weight of dicumyl peroxide (DCP) were added as an initiator, and 15 parts by weight of ethylene bis(tetrabromophthalimide) BT-93 W (from Albemarle Corporation, with a bromine content of 67.2%) were added as a brominated flame retardant, and the above mixture was mixed in toluene, and stirred and dissolved to obtain a uniform resin composition.

E-glass fiber with an average diameter of 5 μm, from China Jushi Co., Ltd.

NE-glass fiber with an average diameter of 5 μm, from China Jushi Co., Ltd.

Quartz fibers with average diameters of 1 μm and 5 μm, from China Shenjiu.

E-glass fiber with an average diameter of 8 μm, from China Jushi Co., Ltd.

Non-woven fabric, prepared from an epoxy binder and an E-glass fiber with an average diameter of 13 μm, from Shaanxi Huatek.

Non-woven fabric, prepared from an acrylate binder and an E-glass fiber with an average diameter of 13 μm, from Shaanxi Huatek.

Non-woven fabric, prepared from a melamine binder and an E-glass fiber with an average diameter of 13 μm, from Shaanxi Huatek.

### Example 1

In this example, a low dielectric loss non-woven fabric is provided, and the low dielectric loss non-woven fabric is composed of a glass fiber and a binder, and the binder is a FEP emulsion.

A specific preparation method includes the following steps:

92 parts by weight of the E-glass fiber (with the average diameter of 5 μm) were impregnated with 8 parts by weight of the FEP binder for 45 min, subjected to papermaking molding, then dried in an oven at 150° C., then sintered in a high temperature oven at 300° C. for 30 min, and taken out and cooled to obtain a non-woven fabric A with a mass per unit area of 20 g/m².

### Example 2

85 parts by weight of the NE-glass fiber (with the average diameter of 5 μm) were impregnated with 15 parts by weight of the FEP binder for 45 min, subjected to papermaking molding, then dried in an oven at 150° C., then sintered in a high temperature oven at 300° C. for 30 min, and taken out and cooled to obtain a non-woven fabric B with a mass per unit area of 75 g/m².

### Example 3

70 parts by weight of the quartz fibers (with the average diameters of 1 μm and 5 μm, at a mass ratio of 1:4) were impregnated with 30 parts by weight of the FEP binder for 45 min, subjected to papermaking molding, then dried in an oven at 140° C., then sintered in a high temperature oven at 220° C. for 28 min, and taken out and cooled to obtain a non-woven fabric C with a mass per unit area of 75 g/m².

### Example 4

85 parts by weight of the E-glass fiber (with the average diameter of 8 μm) were impregnated with 15 parts by weight of the PFA binder for 45 min, subjected to papermaking molding, then dried in an oven at 140° C., then sintered in a high temperature oven at 350° C. for 28 min, and taken out and cooled to obtain a non-woven fabric D with a mass per unit area of 75 g/m².

### Example 5

85 parts by weight of the E-glass fiber (with the average diameter of 8 μm) were impregnated with 15 parts by weight of the polyolefin binder for 45 min, subjected to papermaking molding, then dried in an oven at 120° C., and taken out and cooled to obtain a non-woven fabric E with a mass per unit area of 120 g/m².

### Example 6

85 parts by weight of the E-glass fiber (with the average diameter of 8 μm) were impregnated with 15 parts by weight of the vinyl-modified polyphenylene ether (Mitsubishi Gas Chemical OPE-2ST) binder for 45 min, subjected to papermaking molding, then dried in an oven at 200° C., and taken out and cooled to obtain a non-woven fabric F with a mass per unit area of 120 g/m².

The main materials and parameters of the non-woven fabrics in the above examples are summarized in Table 1.

TABLE 1

| | Example 1 | Example 2 | Example 3 | Example 4 | Example 5 | Example 6 |
|---|---|---|---|---|---|---|
| Non-woven fabric | A | B | C | D | E | F |
| number | | | | | | |
| Binder type | FEP | FEP | FEP | PFA | polyolefin | PPO |
| Binder amount, | 8 | 15 | 30 | 15 | 15 | 15 |
| wt % | | | | | | |
| Glass fiber type | E-glass | NE-glass | Quartz | E-glass | E-glass | E-glass |
| | fiber | fiber | fiber | fiber | fiber | fiber |
| Glass fiber | 5 | 5 | 1 + 5 | 8 | 8 | 8 |
| diameter, μm | | | | | | |
| Mass per unit area | 20 | 75 | 75 | 75 | 120 | 120 |
| of the non-woven | | | | | | |
| fabric, g/m² | | | | | | |

### Example 7

In this example, a PTFE copper clad laminate is provided, and a preparation method specifically includes the steps below.

Step (1): the non-woven fabric A of Example 1 was impregnated with the low-CTE resin A by an sizing glue machine, so as to obtain a prepreg H with a sized resin content of 90%.

Step (2): the prepreg H obtained in step (1) was placed into a vacuum oven, baked at 100° C. for 1 h to remove moisture, then baked at 260° C. for 1 h to remove additives, and then baked at 350° C. for 10 min to obtain a bonding sheet with a thickness of 0.25 mm.

Step (3): one single bonding sheet was covered with copper foils of 1 OZ thickness on the upper and lower sides and subjected to lamination, in which a pressure applied was 400 PSI, and a maximum temperature and a retention time were 380° C./60 min, so as to obtain the PTFE copper clad laminate.

### Example 8

This example differs from Example 7 only in that the non-woven fabric A in step (1) was replaced with the non-woven fabric B to obtain a prepreg I.

### Example 9

This example differs from Example 7 only in that the non-woven fabric A in step (1) was replaced with the non-woven fabric C to obtain a prepreg J.

### Example 10

This example differs from Example 7 only in that the non-woven fabric A in step (1) was replaced with the non-woven fabric D to obtain a prepreg K.

### Example 11

In this example, a high-frequency circuit substrate is provided, and a preparation method specifically includes the steps below.

Step (1): the non-woven fabric E of Example 5 was impregnated with the thermosetting resin A by an sizing glue machine, so as to obtain a prepreg M with a sized resin content of 90%.

Step (2): the prepreg M obtained in step (1) was placed into an oven at 100° C., baked for 1 h to remove solvent, so as to obtain a bonding sheet.

Step (3): resin layers of one single bonding sheet were covered with copper foils of 1 OZ thickness on the upper and lower sides for stacking arrangement, and put into a press for curing to obtain the high-frequency circuit substrate, in which the curing had a temperature of 200° C., a time of 90 min, and a pressure of 50 kg/cm².

### Example 12

In this example, a high-frequency circuit substrate is provided, and a preparation method specifically includes the steps below.

Step (1): the non-woven fabric F of Example 6 was impregnated with the thermosetting resin B by an sizing glue machine, so as to obtain a prepreg N with a sized resin content of 90%.

Step (2): the prepreg N obtained in step (1) was dried in an oven at 100° C. to remove the solvent toluene, so as to obtain a bonding sheet.

Step (3): resin layers of one single bonding sheet were arranged with copper foils of 1 OZ thickness on the upper and lower sides, and laminated and cured under vacuum in a press for 90 min, in which a curing pressure was 50 kg/cm² and a curing temperature is 200° C., so as to obtain the high-frequency circuit substrate.

### Comparative Example 1

This comparative example differs from Example 7 only in that the non-woven fabric A in step (1) was replaced with the non-woven fabric with epoxy binder, and others were exactly the same.

### Comparative Example 2

This comparative example differs from Example 7 only in that the non-woven fabric A in step (1) was replaced with the non-woven fabric with acrylate binder, and others were exactly the same.

### Comparative Example 3

This comparative example differs from Example 7 only in that the non-woven fabric A in step (1) was replaced with the non-woven fabric with melamine binder, and others were exactly the same.

### Comparative Example 4

This comparative example differs from Example 11 only in that the non-woven fabric E in step (1) was replaced with the non-woven fabric with epoxy binder, and others were exactly the same.

### Comparative Example 5

This comparative example differs from Example 12 only in that the non-woven fabric F in step (1) was replaced with the non-woven fabric with epoxy binder, and others were exactly the same.

### Comparative Example 6

This comparative example differs from Example 7 only in that the binder was excessive in the non-woven fabric A in step (1), and a ratio was 50%, and others were exactly the same.

Performance evaluation was performed on the copper clad laminates or high-frequency circuit substrates of Examples 7-12 and Comparative Examples 1-6, and the methods are described below.

1. Dk and Df: SPDR (split post dielectric resonator) method was used to test, a test condition was A state and a frequency was 10 GHz.

2. Peel strength: according to the method from GB/T 4722-2017 7.2.

The test results are shown in Table 2 and Table 3.

TABLE 2

| | Examples 7-12 | | | | | |
|---|---|---|---|---|---|---|
| Indicator | 7 | 8 | 9 | 10 | 11 | 12 |
| Dk (10 GHz) | 2.26 | 2.23 | 2.25 | 2.20 | 2.70 | 2.52 |
| Df (10 GHz) | 0.0012 | 0.0013 | 0.0010 | 0.0012 | 0.0035 | 0.0025 |
| Peel Strength | 1.4 | 1.3 | 1.6 | 1.5 | 0.8 | 0.8 |
| (N/mm) | | | | | | |

TABLE 3

| | Comparative Examples 1-6 | | | | | |
|---|---|---|---|---|---|---|
| Indicator | 1 | 2 | 3 | 4 | 5 | 6 |
| Dk (10 GHz) | 2.28 | 2.29 | 2.30 | 2.75 | 2.55 | 2.33 |
| Df (10 GHz) | 0.0031 | 0.0035 | 0.0041 | 0.0055 | 0.0042 | 0.0028 |
| Peel Strength | 0.6 | 0.6 | 0.6 | 0.5 | 0.5 | 0.5 |
| (N/mm) | | | | | | |

What can be seen from Table 2 and Table 3 is as follows.

It can be seen that for the copper clad laminates in Examples 7-10 which are prepared by mixing PTFE and the non-woven fabrics prepared with low-loss binders, the dielectric loss (Dk (10 GHz) is lower than 2.26, and Df (10 GHz) is lower than 0.0013) and the peel strength (more than or equal to 1.3 N/mm) are obviously better than the performance of copper clad laminates in Comparative Examples 1-3 which are prepared with the common non-woven fabrics.

It can be seen that for the copper clad laminate in Examples 11 which is prepared by the hydrocarbon system and the non-woven fabric prepared with low-loss binder, the dielectric loss and the peel strength are obviously better than the performance of copper clad laminate in Comparative Example 4 which is prepared with the common non-woven fabric.

It can be seen that for the copper clad laminate in Examples 12 which is prepared by the polyphenylene ether system and the non-woven fabric prepared with low-loss binder, the dielectric loss and the peel strength are obviously better than the performance of copper clad laminate in Comparative Example 5 which is prepared with the common non-woven fabric.

The low-loss binder used in Comparative Example 6 is excessive, resulting in excessively high dielectric loss of the board.

The applicant has stated that although the low dielectric loss non-woven fabric, the preparation method thereof and the use thereof in the present application are described by the above embodiments, the present application is not limited to the above embodiments, which means that the present application does not necessarily rely on the above embodiments to be implemented. It should be apparent to those skilled in the art that any improvement of the present application, the equivalent replacement of various raw materials of the product in the present application, the addition of auxiliary components, the selection of specific methods, etc., all fall within the protection scope and disclosure scope of the present application.

What is claimed is:

1. A low dielectric loss non-woven fabric, wherein the low dielectric loss non-woven fabric is composed of an inorganic fiber and a binder, and the binder is any one or a combination of at least two of a fluorine-containing resin emulsion, a polyolefin emulsion, a polyphenylene ether resin or a cyanate ester resin.

2. The low dielectric loss non-woven fabric according to claim 1, wherein a weight percentage of the inorganic fiber is 60-95% in the low dielectric loss non-woven fabric, and a weight percentage of the binder is 5-40%.

3. The low dielectric loss non-woven fabric according to claim 1, wherein the binder is a fluorine-containing resin emulsion.

4. The low dielectric loss non-woven fabric according to claim 1, wherein the fluorine-containing resin emulsion is selected from any one or a combination of at least two of a polyperfluoroethylene propylene emulsion, a polyvinylidene fluoride emulsion, a tetrafluoroethylene-perfluoroalkyl vinyl ether copolymer emulsion, an ethylene-tetrafluoroethylene copolymer emulsion, a polychlorotrifluoroethylene emulsion or an ethylene-chlorotrifluoroethylene copolymer emulsion.

5. The low dielectric loss non-woven fabric according to claim 1, wherein, a solid content of the fluorine-containing resin emulsion is 30-70%.

6. The low dielectric loss non-woven fabric according to claim 1, wherein, a particle size of the fluorine-containing resin is 0.10-0.40 μm in the fluorine-containing resin emulsion.

7. The low dielectric loss non-woven fabric according to claim 1, wherein the polyolefin emulsion is selected from any one or a combination of at least two of an unsaturated polybutadiene resin emulsion, a styrene-butadiene-styrene triblock copolymer emulsion, a hydrogenated styrene-butadiene-styrene triblock copolymer emulsion or a styrene-butadiene resin emulsion.

8. The low dielectric loss non-woven fabric according to claim 1, a solid content of the polyolefin emulsion is 30-70%.

9. The low dielectric loss non-woven fabric according to claim 1, wherein the inorganic fiber is selected from any one or a combination of at least two of an E-glass fiber, an NE-glass fiber, an L-glass fiber or a quartz fiber.

10. The low dielectric loss non-woven fabric according to claim 1, wherein an average diameter of the inorganic fiber is less than 10 μm.

11. The low dielectric loss non-woven fabric according to claim 1, wherein an average length of the inorganic fiber is 1-100 mm.

12. The low dielectric loss non-woven fabric according to claim 1, wherein a mass per unit area of the low dielectric loss non-woven fabric is 20-200 g/m², preferably 20-100 g/m².

13. A preparation method of the low dielectric loss non-woven fabric according to claim 1, comprising the following steps: mixing an inorganic fiber with a binder, impregnating the fiber, subjecting them to papermaking molding, and drying them, so as to obtain the low dielectric loss non-woven fabric.

14. A prepreg, comprising the low dielectric loss non-woven fabric according to claim 1 and a resin composition adhered thereto by impregnation.

15. The prepreg according to claim 14, the resin composition is a fluorine-containing resin emulsion.

16. The prepreg according to claim 14, the fluorine-containing resin emulsion is selected from any one or a combination of at least two of a polyperfluoroethylene propylene emulsion, a polyvinylidene fluoride emulsion, a tetrafluoroethylene-perfluoroalkyl vinyl ether copolymer emulsion, an ethylene-tetrafluoroethylene copolymer emulsion, a polychlorotrifluoroethylene emulsion or an ethylene-chlorotrifluoroethylene copolymer emulsion.

17. A copper clad laminate, comprising a copper foil and the prepreg according to claim 14.

18. A printed circuit board, comprising a copper foil and the prepreg according to claim 14.
